(19) United States
(12) Patent Application Publication
(10) Pub. No.: US 2014/0340107 A1
(43) Pub. Date: Nov. 20, 2014

(54) BGA TEST SOCKET

(71) Applicant: EXPERT INTERNATIONAL MERCANTILE CORPORATION, Hsinchu City (TW)

(72) Inventor: Wei-Chih SUN, Hsinchu (TW)

(21) Appl. No.: 13/896,916

(22) Filed: May 17, 2013

(51) Int. Cl. G01R 1/04

(52) U.S. Cl. CPC G01R 1/0441
USPC 324/756.02

(57) ABSTRACT

For testing a high density BGA package, a central pressure block is designed to press against the chip of the package during test in a test socket. High density socket probe causes high pressure against the package, especially the area under the chip. With the central pressure block of the present invention, the high density BGA package is prevented from deformation because the central pressure block pressing downward against the chip, which balances the pressure coming upward from the high density socket probes under the circuit board in the area under the chip.

### BACKGROUND

1. Technical Field

The present invention relates to a test socket for testing a ball grid array (BGA) package, especially suitable for testing a high density BGA package.

2. Description of Related Art

FIG. 1 is a prior art test socket

FIG. 1 is a prior art test socket 100 having a top cover 10 and a socket seat 13. A hinge mechanism 12 is configured between the top cover 10 and the socket seat 13 so that the top cover 10 is able to close against the socket seat 13 during test. The top cover 10 has a frame 102, and a window 101 surrounded by the frame 102.

FIGS. 2A˜2B is the socket seat of FIG. 1.

FIG. 2A shows that the socket seat 13 has a central recess 133 and a seat wall 132 surrounding the recess 133. A flatbed 135 is configured on the bottom of the recess 133 and surrounded by the seat wall 132. An array of socket probe 14 is configured in the flatbed 135 of the socket seat 13.

FIG. 2B is a section view according to line AA′ of FIG. 2A. The recess 133 is surrounded by the seat wall 132. The socket probe 14 is protruded above the top surface of the flatbed 135. The socket probe 14 is elastic so as to provide a pressure upward against the ball grid of a BGA package under test. The elasticity of the socket probe 14 is provided by an underlain spring 141.

FIGS. 3A˜3C is a prior art of a relatively lower density BGA package.

FIG. 3A is a top view of a relatively lower density BGA package 200. The package has a chip 16 mounted on the center top of a circuit board 15. A metal frame 17 braces the periphery of the circuit board 15 to strengthen the package 200 and prevent the package 200 from being deformed.

FIG. 3B is a section view according to line BB′ of FIG. 3A. FIG. 3B shows that the chip 16 is mounted on the center top of the circuit board 15. The metal frame 17 braces the periphery of the circuit board 15. The relatively lower density ball grid array 18 is configured on the bottom of the circuit board 15.

FIG. 3C is a bottom view of FIG. 3A. FIG. 3C shows that the relatively lower density ball grid array 18 is configured on a bottom of the circuit board 15.

FIGS. 4A˜4B is prior art of a relatively lower density BGA package under test

FIG. 4A shows the relatively lower density BGA package 200 under test. The top cover 10 of the test socket 100 closes down against the socket seat 13. A peripheral pressure unit 21 pressing against the BGA package 200. Please pay attention that the peripheral pressure unit 21 presses the metal frame 17 only. There is no pressure pressing against the chip 16 from top.

FIG. 4B shows the relatively lower density BGA package 200 keeps the same profile after test. Please pay attention that the lower density socket probes 14 applies lower pressure against the circuit board 15 under the chip 16. However, package deformation shall occur when the number of probes 14 is relatively higher. Nowadays, higher and higher the ball grid array for a BGA package becomes as the semiconductor technology is improved swiftly.

FIGS. 5A˜5C is a prior art of a relatively higher density BGA package.

FIG. 5A is a top view of a relatively higher density BGA package 300. The package 300 has a chip 162 mounted on the center top of a circuit board 15. A metal frame 17 braces the periphery of the circuit board 15 to strengthen the package 300 and prevent the package 300 from being deformed.

FIG. 5B is a section view according to line CC′ of FIG. 5A. FIG. 5B shows that the chip 162 is mounted on the center top of the circuit board 15. The metal frame 17 braces the periphery of the circuit board 15. A relatively higher density ball grid array 182 is configured on the bottom of the circuit board 15.

FIG. 5C is a bottom view of FIG. 5A. FIG. 5C shows that the relatively higher density ball grid array 182 is configured on a bottom of the circuit board 15.

FIGS. 6A˜6B is a prior art of a relatively higher density BGA package under test

FIG. 6A shows the relatively higher density BGA package 300 under test. The top cover 10 of the test socket 100 closes down against the socket seat 13. A peripheral pressure unit 21 pressing against the relatively higher density BGA package 300. Please pay attention that the peripheral pressure unit 21 presses the metal frame 17 only. There is no pressure pressing against the chip 162 from top.

FIG. 6B shows the high density BGA package 300 is deformed under the chip 162 during test because huge pressure pressing against the circuit board 15 due to the high density probes 142 in the area under the chip 162. Please pay attention to the socket probes 142 under the chip 16. The higher number of probe 142 applies a higher pressure against the circuit board 15 in the area under the chip 16. Package deformation occurs during test. The deformation may cause break to the chip 162. Some 17 gram pressure a socket probe 142 contributes, if say, 20*20 probes under the circuit board 15 in the area under the chip 162, there shall be 20*20*17=6800 gram pressure applying against the circuit board 15 under the chip 162. The 6800 gram is a high pressure during test, which may cause a permanent damage to the BGA package 300 if test under the traditional test socket 100.

A solution to prevent the package deformation problem for testing a high density BGS package is eager to submit.

### BRIEF DESCRIPTION OF THE DRAWINGS

FIG. 1 is a prior art test socket

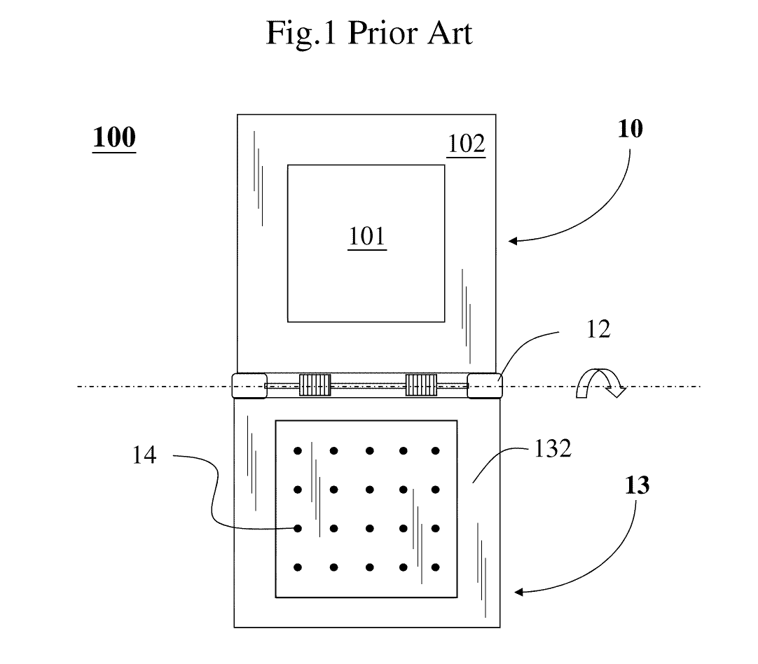

FIGS. 2A˜2B is the socket seat of FIG. 1.

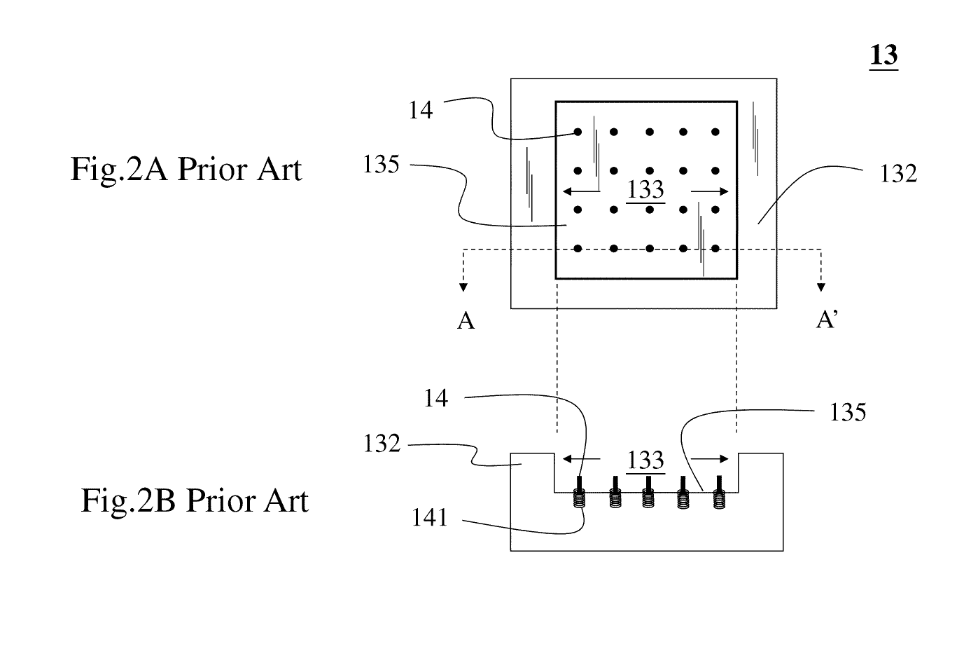

FIGS. 3A˜3C is a prior art of a relatively lower density BGA package.

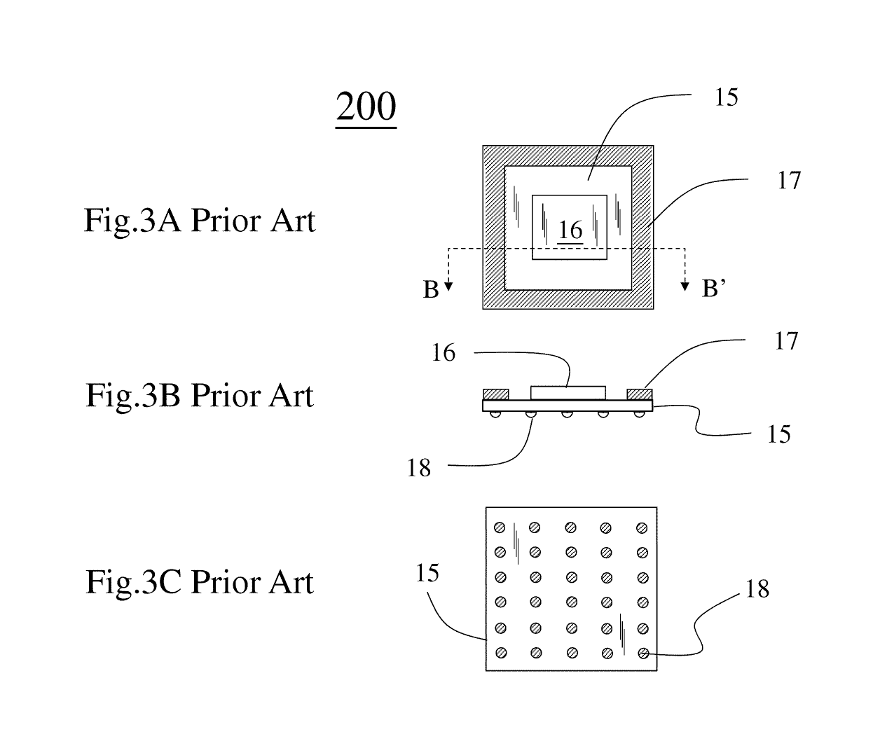

FIGS. 4A˜4B is prior art of a relatively lower density BGA package under test

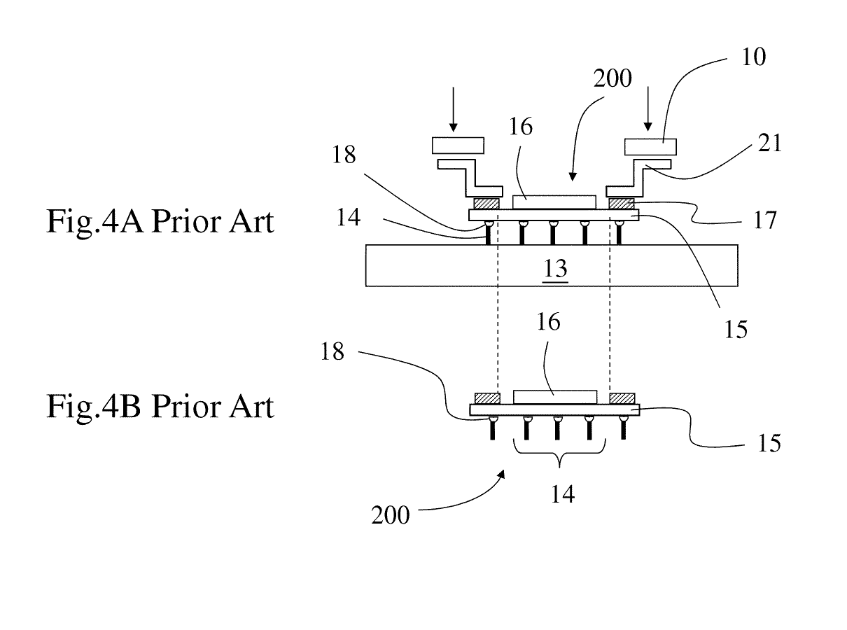

FIGS. 5A˜5C is a prior art of a relatively higher density BGA package.

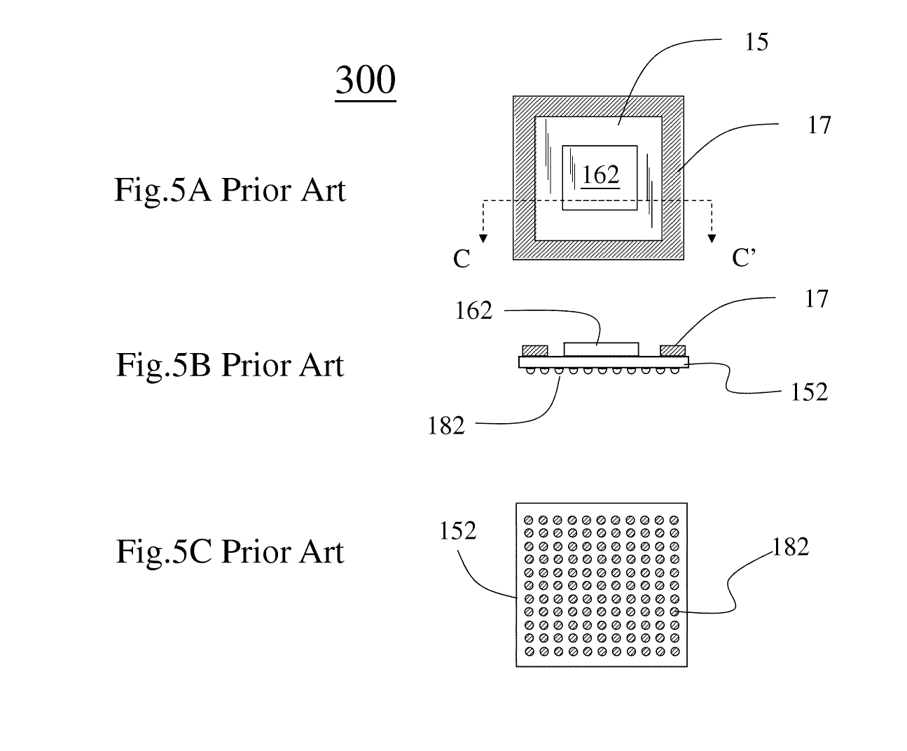

FIGS. 6A˜6B is a prior art of a relatively higher density BGA package under test

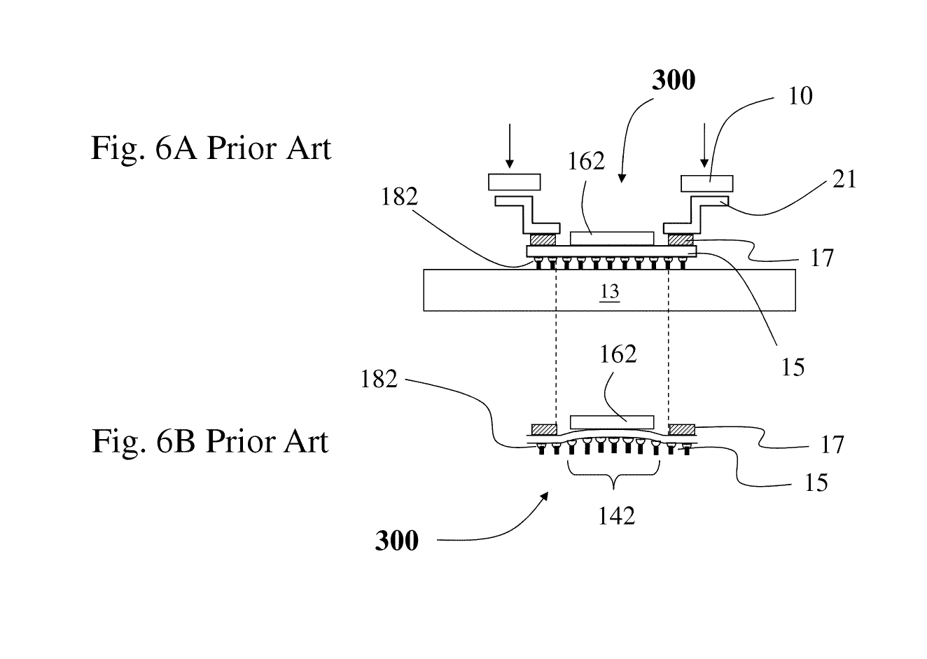

FIGS. 7A˜7C is a peripheral pressure unit of an embodiment according to the present invention.

FIGS. 8A˜8C is a central pressure block of the embodiment according to the present invention.

FIGS. 9A˜9C is a combination status for the central pressure block combining the peripheral pressure unit according to the present invention.

FIGS. 10A˜10B is a relatively higher density BGA package under test according to the present invention.

FIG. 11 is a cooling unit configured on a top of the central pressure block under testing.

FIGS. 12A˜12B pictures of an actual test socket according to the present invention.

### DETAILED DESCRIPTION OF THE INVENTION

The peripheral pressure unit is modified and a central pressure block 210 is newly created to match with the modified pressure unit 250. The improved test socket solves the deformation problem for a relatively higher density BGA package during test.

A central pressure block is designed to press against the relatively higher density BGA package 300 under test so that the circuit board 15 under the chip 162 shall not be deformed by the pressure upward from the spring probes 142. The central pressure block 210 has an upper block 214 and a lower block 213. The lower block 213 is protruded downward from the upper block 214. The lower block 213 is configured to press against the high density BGA package 300 from top during test.

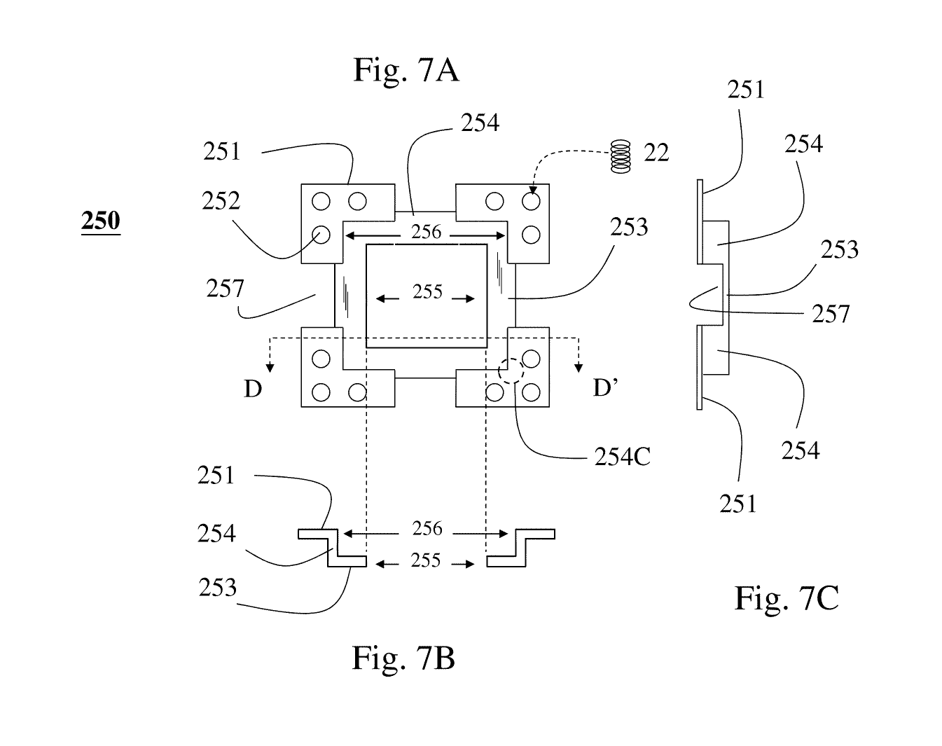

FIGS. 7A˜7C is a peripheral pressure unit of an embodiment according to the present invention.

FIG. 7A shows a top view of the improved peripheral pressure unit. A peripheral pressure unit 250 has a central recess 256. A rectangular wall 254 has four corners 254C, the rectangular wall 254 surrounds the central recess 256; an upper flat 251 extends outward from a top of the wall 254; a lower flat 253 extends inward from a bottom of the wall 254. A window 255 is enclosed by the lower flat 253.

The opening 255 is configured in the bottom center of the recess 256. The dimension of the rectangular wall 254 is designed to fit in the recess 133 of the BGA test socket 100. There are four L-shaped top flats 251, each top flat 251 is configured to bracket one of the four corners of the rectangular wall 254. At least a blind hole 252 is made on each top flat 251. A spring 22 is suitable to fit in the blind hole 252 with upper portion protruded above the top surface of the top flat 251 so that the top cover 10 is able to press against the spring 22 when the socket 100 closes. The dimension of the rectangular wall 254 is designed to fit in the recess 133 of the socket 100. The dimension of the opening 255 is designed to be larger than the dimension of the chip 162 so that the backside of the chip 162 is able to fully expose after the peripheral pressure unit 250 fits in the recess 133. An opening 257 is formed between two neighboring top flat 251. Please pay attention that the opening 257 extends downward to the top surface of the bottom flat 253 (FIG. 7C).

FIG. 7B is a section view according to line DD′ of FIG. 7A. FIG. 7B shows the peripheral pressure unit 250 has a recess 256 and a window 255 configured in the bottom center of the recess 256. The peripheral pressure unit 250 has a top flat 251, a rectangular wall 254, and a bottom flat 253. The upper flat 251 extends outward from a top of the wall 254; the lower flat 253 extends inward from a bottom of the wall 254. A window 255 is enclosed by the lower flat 253.

FIG. 7C is a side view to FIG. 7A. FIG. 7C shows that the rectangular wall 254 is partially cut away in between the upper flat 251 so that the opening 257 extends downward to the top surface of the bottom flat 253.

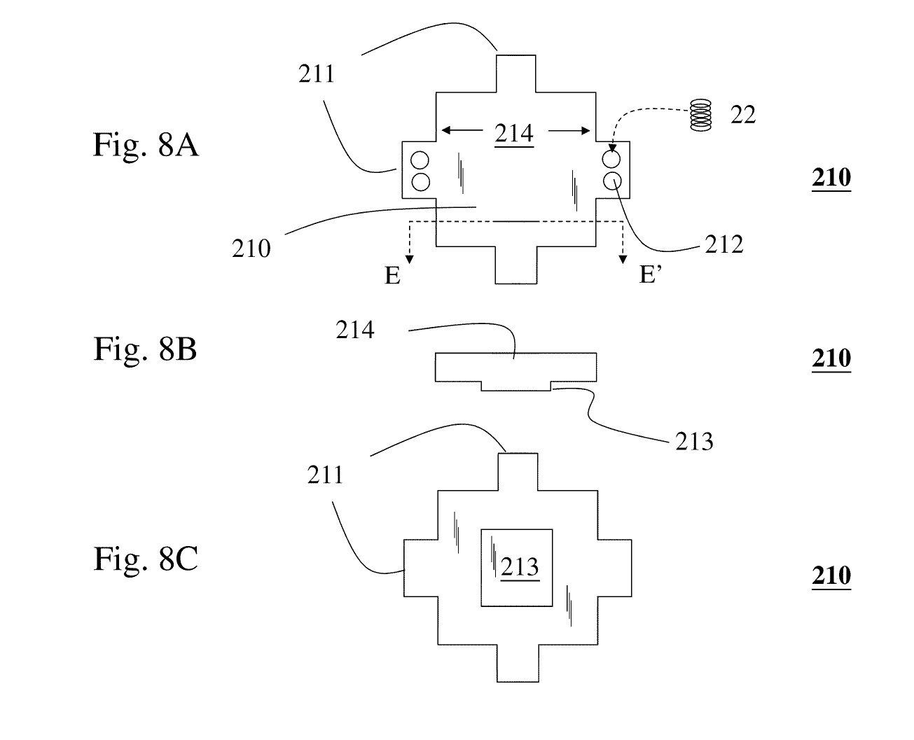

FIGS. 8A˜8C is a central pressure block of the embodiment according to the present invention.

FIG. 8A is a top view of the central pressure block 210. The central pressure block 210 has an upper block 214. There are four side tabs 211; each tab 211 extends from one of the four sides of the upper block 214. The side tab 211 is designed to fit in the opening 257 of the peripheral pressure unit 250. There are two blind holes 212 made in the left side tab and right side tab 211. Each of the blind holes is designed to house a spring 22. The spring 22 is configured to protrude above the top surface of the central block 214 so that the top cover 10 is able to close down and presses against the central pressure block 210 during test.

FIG. 8B is a section view according to line EE′ of FIG. 8A. The central pressure block 210 has an upper block 214 and a lower block 213. The lower block 213 is protruded downward from a center bottom of the upper block 214.

FIG. 8C is a bottom view of FIG. 8A. The lower block 213 is protruded downward from the upper block 214. The dimension of the lower block 213 is near or larger than that of the chip 162 under test so that the lower block 213 is able to press against the chip 162 during test.

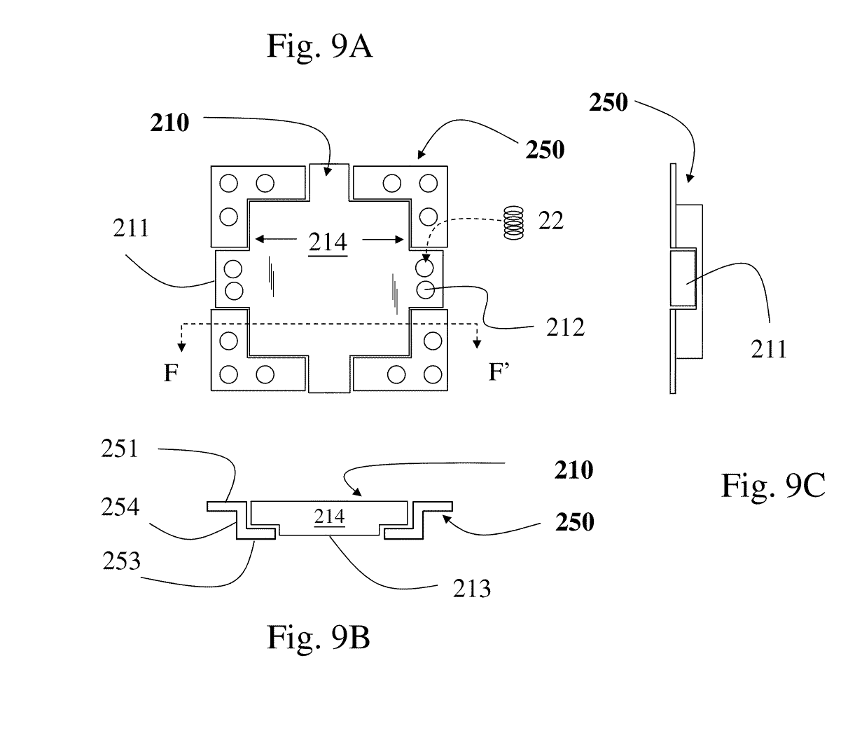

FIGS. 9A˜9C is a combination status for the central pressure block combining the peripheral pressure unit according to the present invention.

FIG. 9A is a top view of a combination status of the peripheral pressure unit 250 combining the central pressure block 210. The upper block 214 fits in the recess 256 of the peripheral pressure unit 250. The side tabs 211 fit in the opening 257 of the peripheral pressure unit 250.

FIG. 9B is a section view according to line FF′ of FIG. 9A. FIG. 9B shows that the upper block 214 fits in the recess 256 of the peripheral pressure unit 250. The lower block 213 fits in the window 255 of the peripheral pressure unit 250.

FIG. 9C is a side view of FIG. 9A. FIG. 9C shows that the side tab 211 fits in the opening 257 of the peripheral pressure unit 250.

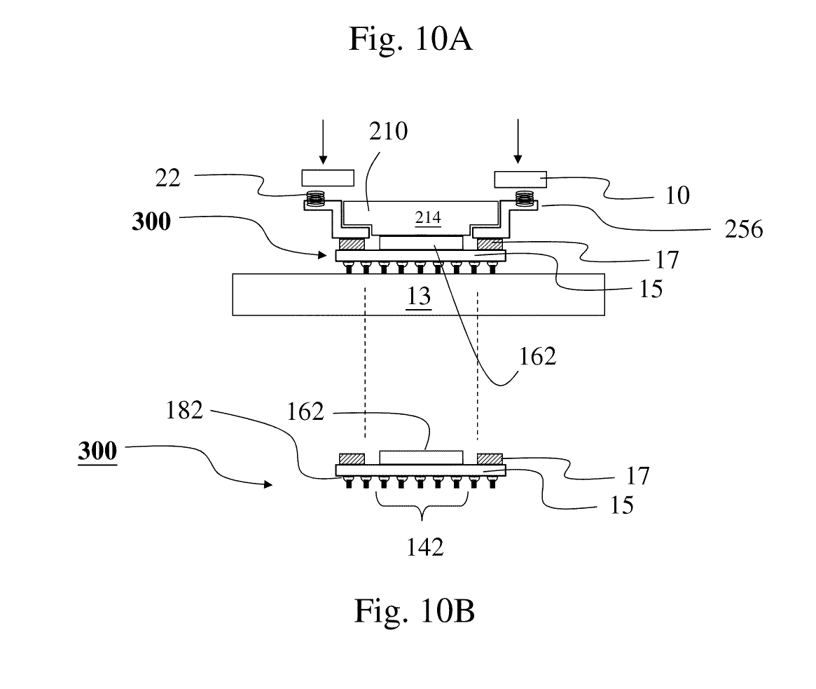

FIGS. 10A˜10B is a relatively higher density BGA package under test according to the present invention.

FIG. 10A shows a relatively higher density BGA package 300 is configured in the test socket 100 for test. The relatively higher density BGA package 300 is pressed by the peripheral pressure unit 250 against a periphery of the package 300, and pressed by the central pressure block 210 against the center of the package 300 so that the circuit board 13 is not deformed by the pressure coming from the socket probe 142.

FIG. 10B shows the relatively higher density BGA package 300 during the period of the test. FIG. 10B shows that the circuit board 15 is not deformed by the pressure coming from the higher density socket probes 142. With the present invention, the relatively higher density BGA package 300 keeps the same profile during test.

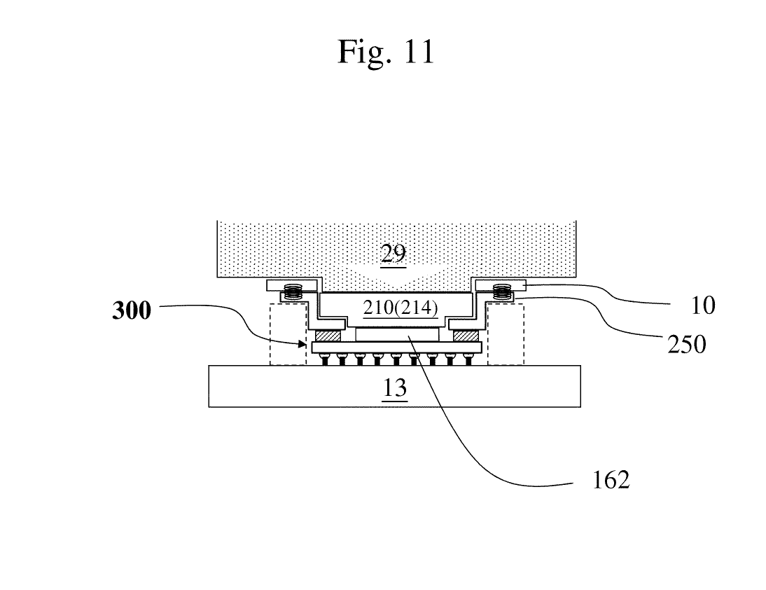

FIG. 11 is a cooling unit configured on a top of the central pressure block under testing.

FIG. 11 shows that a cooling unit 29 is able to contact the top of the central pressure block 210 so that the heat generated from the chip 162 can be transferred to the cooling unit for heat dissipation.

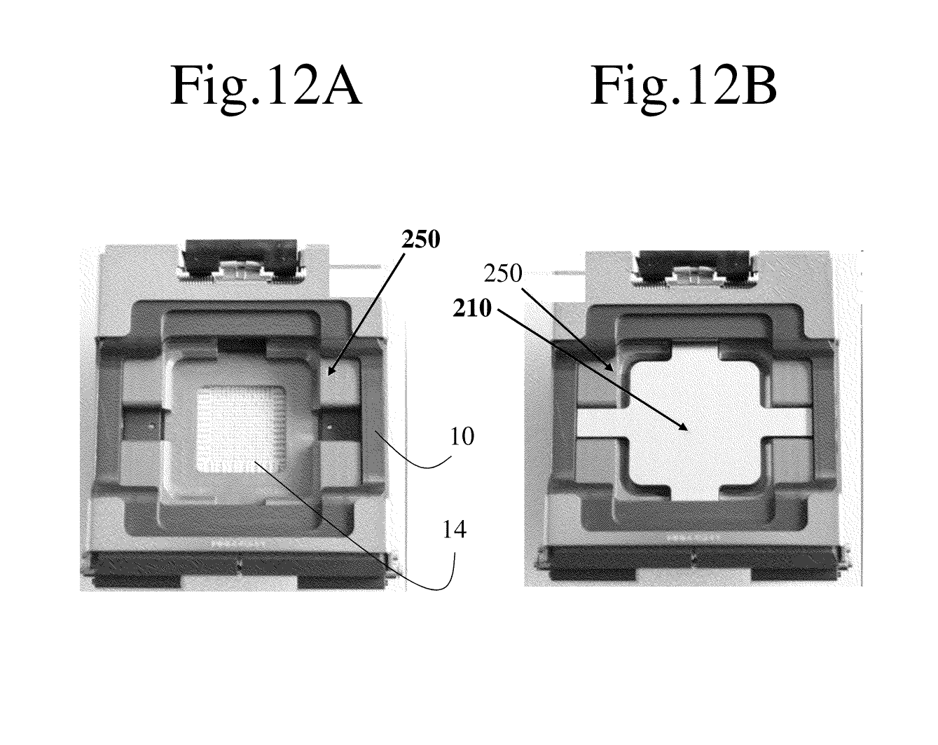

FIGS. 12A˜12B pictures of an actual test socket according to the present invention.

FIG. 12A is a top view of the socket 100 loaded with the modified peripheral pressure unit 250 according to the present invention, however, without having a chip inside in the picture. An array of the socket probe 14 is shown in the center of the socket seat 13.

FIG. 12B is a top view of the socket 100 loaded with the modified peripheral pressure unit 250 and the central pressure block 210 according to the present invention.

Both the peripheral pressure unit 250 and the central pressure block 210 are made of metal so that the heat generated from the package 162 can be conducted for heat dissipation during test.

While several embodiments have been described by way of example, it will be apparent to those skilled in the art that various modifications may be configured without departing from the spirit of the present invention. Such modifications are all within the scope of the present invention, as defined by the appended claims.

What is claimed is:

1. A BGA test socket, comprising:
a peripheral pressure unit, further comprising:
a central recess;
a rectangular wall surrounding the central recess;
an upper flat, extending outward from a top of the wall;
a lower flat; extending inward from a bottom of the wall; and
a window, enclosed by the lower flat;
a central pressure block, further comprising:
an upper block, configured to fit in the central recess; and
a lower block, protruded downward from the upper block; configured to fit in the window.

2. A BGA test socket as claimed in claim 1, wherein the upper flat is an L shaped metal, in a top view, bracketing one of the corners of the rectangular wall.

3. A BGA test socket as claimed in claim 1, further comprising:
a first hole, configured on top of the upper flat, adapted for housing a first spring.

4. A BGA test socket as claimed in claim 1, further comprising:
an opening, configured between two upper flats, the opening extending downward to the top surface of the lower flat.

5. A BGA test socket as claimed in claim 1, further comprising:
a side tab, protruded from one side of the upper block.

6. A BGA test socket as claimed in claim 5, further comprising:
a second hole, configured on a top of the side tab, adapted for housing a second spring.

7. A BGA test socket as claimed in claim 1, wherein the peripheral pressure unit is made of a metal.

8. A BGA test socket as claimed in claim 1, wherein the central pressure block is made of a metal.
